(19) United States
(12) Patent Application Publication
(10) Pub. No.: US 2023/0320152 A1
(43) Pub. Date: Oct. 5, 2023

(54) DISPLAY APPARATUS

(71) Applicant: SAMSUNG DISPLAY CO., LTD., Yongin-si (KR)

(72) Inventors: Seonyoung CHOI, Yongin-si (KR); Gyungsoon PARK, Yongin-si (KR)

(21) Appl. No.: 18/121,480

(22) Filed: Mar. 14, 2023

(30) Foreign Application Priority Data
Mar. 30, 2022 (KR) 10-2022-0039873

(51) Int. Cl. H10K 59/131

(52) U.S. Cl. CPC H10K 59/131

(57) ABSTRACT

The invention relates to display apparatus. The display apparatus includes: a substrate including a display area and a peripheral area outside the display area, where the display area includes a plurality of first islands, a first connector, and a first through-portion; a plurality of unit display parts arranged on the plurality of first islands, respectively; a first common voltage line and a second common voltage line arranged on one side of the peripheral area; a driving circuit part arranged between the first common voltage line and the second common voltage line; and a plurality of shield parts disposed on the driving circuit part and apart from each other.

This application claims priority to Korean Patent Application No. 10-2022-0039873, filed on Mar. 30, 2022, and all the benefits accruing therefrom under 35 U.S.C. § 119, the content of which in its entirety is herein incorporated by reference.

### BACKGROUND

### 1. Field

One or more embodiments relate to a display apparatus.

### 2. Description of the Related Art

With the rapid development of the display field that visually expresses various pieces of electric signal information, various flat display apparatuses having excellent characteristics, such as a slim profile, light weight, low power consumption, and the like have been introduced. With the development of display-related technology, a flexible display apparatus that is foldable or rollable has been studied and developed. Furthermore, research has been actively carried out into a stretchable display apparatus that may be changed in various shapes.

### SUMMARY

One or more embodiments include a display apparatus having a transformable shape.

Additional aspects will be set forth in part in the description which follows and, in part, will be apparent from the description, or may be learned by practice of the presented embodiments of the disclosure.

According to one or more embodiments, a display apparatus includes: a substrate including a display area and a peripheral area outside the display area, where the display area includes a plurality of first islands, a first connector, and a first through-portion; a plurality of unit display parts arranged on the plurality of first islands in a one-to-one manner; a first common voltage line and a second common voltage line arranged on one side of the peripheral area; a driving circuit part arranged between the first common voltage line and the second common voltage line; and a plurality of shield parts disposed on the driving circuit part and apart from each other.

The first common voltage line may be connected to the plurality of unit display parts, and the second common voltage line may be connected to the plurality of shield parts.

The peripheral area may include a plurality of second islands, a second connector, and a second through-portion, and shapes of the plurality of second islands may be the same as shapes of the plurality of first islands.

The second common voltage line may extend in one direction, and bend along shapes of the plurality of second islands and the second connector.

The driving circuit part may include a plurality of unit driving circuit parts, and the plurality of unit driving circuit parts may be arranged on the plurality of second islands, respectively.

The plurality of shield parts may overlap the plurality of unit driving circuit parts, respectively.

A light-emitting element may be arranged in each of the plurality of unit display parts, the light-emitting element may include a pixel electrode, an emission layer, and an opposite electrode, and the plurality of shield parts each may include the same material as a material of the pixel electrode, and be provided in the same layer as a layer in which the pixel electrode is provided.

A planarization layer may be disposed between the driving circuit part and the plurality of shield parts; the second common voltage line may be disposed below the planarization layer; and the plurality of shield parts may be connected to the second common voltage line through a contact hole in the planarization layer.

The peripheral area may include a plurality of second islands, a second connector, and a second through-portion, and the plurality of shield parts may be arranged on the plurality of second islands, respectively, and connected to the second common voltage line through the contact hole on the plurality of second islands.

A first planarization layer and a second planarization layer may be stacked between the driving circuit part and the plurality of shield parts, the second common voltage line may be disposed between the first planarization layer and the second planarization layer, and the plurality of shield parts may be connected to the second common voltage line through a contact hole in the second planarization layer.

The peripheral area may include a plurality of second islands, a second connector, and a second through-portion, where a first planarization layer and a second planarization layer may be stacked on the plurality of second islands and the second connector, where the second common voltage line may be disposed between the first planarization layer and the second planarization layer on the plurality of second islands, and where the second common voltage line may be disposed under the first planarization layer on the second connector.

A first planarization layer and a second planarization layer may be stacked between the driving circuit part and the plurality of shield parts, the second common voltage line may include a lower layer and an upper layer, the lower layer may be under the first planarization layer, the upper layer may be between the first planarization layer and the second planarization layer, and the lower layer may be connected to the upper layer through a contact hole.

The driving circuit part may include a first driving circuit group and a second driving circuit group each including unit driving circuit parts, the second common voltage line may include a (2-1)st common voltage line and a (2-2)nd common voltage line, and the (2-2)nd common voltage line may be arranged between the first driving circuit group and the second driving circuit group.

The peripheral area may include a plurality of second islands, a second connector, and a second through-portion, and shapes of the plurality of second islands may be different from shapes of the plurality of first islands.

The driving circuit part may include a plurality of unit driving circuit parts, and one of the plurality of shield parts may cover an entirety of one unit driving circuit part arranged on one of the plurality of second islands.

According to one or more embodiments, a display apparatus includes: a substrate including a display area and a peripheral area, where the display area includes a plurality of first islands and a first connector, and the peripheral area including a plurality of second islands and a second connector; a plurality of unit display parts arranged on the plurality of first islands in a one-to-one manner; a driving circuit part in the peripheral area, configured to transfer signals to the plurality of unit display parts and including a plurality of unit driving circuit parts arranged on the plurality of second islands; a plurality of shield parts overlapping the plurality of unit driving circuit parts, respectively; in the peripheral area, a first common voltage line arranged between the driving circuit part and the display area; and, in the peripheral area, a second common voltage line arranged between the driving circuit part and an edge of the substrate, where the plurality of shield parts are connected to the second common voltage line.

The first common voltage line may be connected to the plurality of unit display parts.

The second common voltage line may extend in one direction, and bend along shapes of the plurality of second islands and the second connector.

A light-emitting element may be arranged in each of the plurality of unit display parts, the light-emitting element may include a pixel electrode, an emission layer, and an opposite electrode, and the plurality of shield parts each may include the same material as a material of the pixel electrode, and be provided in the same layer as a layer in which the pixel electrode is provided.

The driving circuit part may include a first driving circuit group including first unit driving circuit parts and a second driving circuit group including second unit driving circuit parts, where the second common voltage line may include a (2-1)st common voltage line and a (2-2)nd common voltage line, and where the (2-2)nd common voltage line may be arranged between the first driving circuit group and the second driving circuit group.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is an enlarged schematic plan view of a region A of FIG. 1;

FIG. 3A is a view of a shape when a substrate of a display apparatus transforms, according to an embodiment;

FIG. 3B is a view of a shape when a substrate of a display apparatus transforms, according to an embodiment;

FIG. 4 is a schematic plan view of a unit part of FIG. 2;

FIG. 5 is a schematic cross-sectional view of an example of the unit part, taken along line I-I′ of FIG. 4;

FIG. 6 is a schematic plan view of a region B of FIG. 1 according to an embodiment;

FIG. 7 is a schematic cross-sectional view of an example of the region B, taken along line II-II′ of FIG. 6;

FIG. 8 is a schematic cross-sectional view of another example of the region B, taken along line II-II′ of FIG. 6;

FIG. 9 is a schematic cross-sectional view of still another example of the region B, taken along line II-II′ of FIG. 6;

FIG. 10 is a schematic cross-sectional view of yet another example of the region B, taken along line II-II′ of FIG. 6;

FIG. 11 is a schematic plan view of a region B of FIG. 1 according to another embodiment; and

FIG. 12 is a schematic plan view of a region B of FIG. 1 according to still another embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various components, such components must not be limited to the above terms. The above terms are used to distinguish one component from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or components but do not preclude the addition of one or more other features or components.

It will be further understood that, when a layer, region, or component is referred to as being “on” another layer, region, or component, it can be directly or indirectly on the other layer, region, or component. That is, for example, intervening layers, regions, or components may be present.

Sizes of elements in the drawings may be exaggerated or reduced for convenience of explanation. As an example, the size and thickness of each element shown in the drawings are arbitrarily represented for convenience of description, and thus, the present disclosure is not necessarily limited thereto.

In the case where a certain embodiment may be implemented differently, a specific process order may be performed in the order different from the described order. As an example, two processes successively described may be simultaneously performed substantially or performed in the opposite order.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or component is referred to as being “electrically connected” to another layer, region, or component, it may be “directly electrically connected” to the other layer, region, or component or may be “indirectly electrically connected” to other layer, region, or component with other layer, region, or component interposed therebetween.

Hereinafter, embodiments will be described with reference to the accompanying drawings, where like reference numerals refer to like elements throughout and a repeated description thereof is omitted.

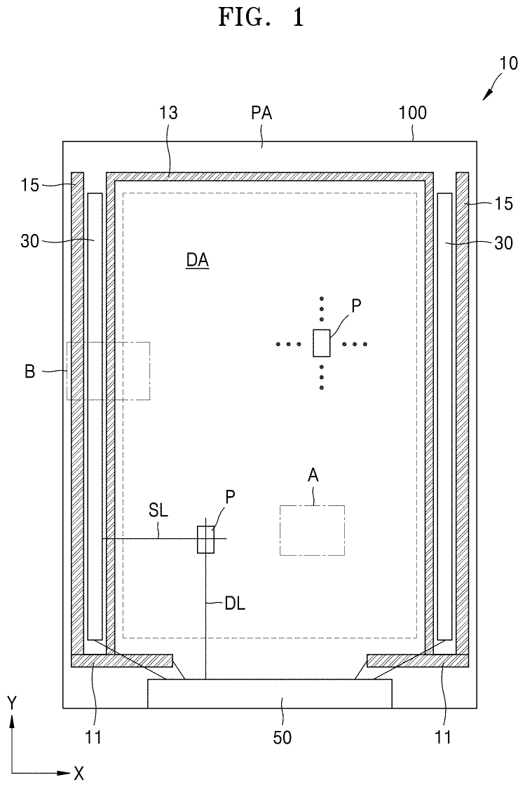

FIG. 1 is a schematic plan view of a display apparatus 10 according to an embodiment.

Referring to FIG. 1, the display apparatus 10 includes a display area DA and a peripheral area PA around the display area DA, where the display area DA and the peripheral area PA may be defined in the substrate 100.

The substrate 100 may include various materials. Specifically, the substrate 100 may include glass, metal, an organic material, or the like.

In an embodiment, the substrate 100 may include a flexible material. As an example, the substrate 100 may include bendable, foldable, or rollable material. The flexible material of the substrate 100 may be ultra-thin glass, metal, or plastic. In the case where the substrate 100 includes plastic, the substrate 100 may include polyimide (“PI”). As another example, the substrate 100 may include a different kind of plastic material.

A plurality of pixels P may be arranged in the display area DA to display images. Each pixel P may include a plurality of light-emitting elements each emitting red, green, blue, or white light. A light-emitting element may be an organic light-emitting element or an inorganic light-emitting element. However, other light-emitting elements may be used. A plurality of pixel circuits for implementing the plurality of light-emitting elements may be arranged in the display area DA. A pixel circuit may include a thin-film transistor TFT, a storage capacitor, and the like.

The display area DA may be configured to display preset images by using light emitted from the pixels P. The pixels P may be provided in an array configuration of an n×m matrix. In the present specification, as described above, the pixel P denotes a sub-pixel that emits red, green, blue, or white light.

The peripheral area PA is arranged outside the display area DA. A driving circuit part 30, a first common voltage line 13, a second common voltage line 15, and a terminal part 50 may be arranged in the peripheral area PA, where the driving circuit part 30 provides signals to the display area DA, and the first common voltage line 13 and the second common voltage line 15 are arranged on two opposite sides of the driving circuit part 30, respectively.

The driving circuit part 30 may be arranged to correspond to the left side and/or right side of the display area DA. The driving circuit part 30 may be configured to provide scan signals for driving the pixels P arranged in the display area DA. Scan signals generated by the driving circuit part 30 may be provided to the pixels P through a scan line SL. The driving circuit part 30 on the left of the display area DA may be synchronized with the driving circuit part 30 on the right of the display area DA by synchronized clock signals. Though it is shown in the drawing that the driving circuit parts 30 are arranged on the left and right of the display area DA, respectively, the driving circuit part 30 may be arranged on only the left or right of the display area DA. The driving circuit part 30 may be connected to the terminal part 50.

The first common voltage line 13 and the second common voltage line 15 may be arranged on two opposite sides of the driving circuit part 30, respectively. That is, the driving circuit part 30 may be arranged between the first common voltage line 13 and the second common voltage line 15. The first common voltage line 13 and the second common voltage line 15 may be connected to each other to receive the same constant voltage. As an example, the first common voltage line 13 and the second common voltage line 15 may each branch off from a main common voltage line 11. The first common voltage line 13 may be adjacent to the display area DA and may provide a common voltage to the pixels P arranged in the display area DA. The common voltage may be provided to a cathode of a light-emitting element implementing the pixel P. The second common voltage line 15 may be arranged outside the driving circuit part 30, that is, in the edge of the substrate 100, and may protect the driving circuit part 30 from electrostatic discharge.

The first common voltage line 13 may surround at least a portion of the display area DA. The first common voltage line 13 may be arranged to correspond to three sides including the left, right, and upper sides of the display area DA. Though it is shown in the drawing that the ends of the second common voltage line 15 are open, the ends of the second common voltage line 15 on the left and right sides may be connected to each other. However, various modifications may be made. In addition, though it is shown in the drawing that the first common voltage line 13 and the second common voltage line 15 are arranged in straight lines, the first common voltage line 13 and the second common voltage line 15 may be arranged in curved shapes in another embodiment. The first common voltage line 13 and the second common voltage line 15 may each be connected to the terminal part 50.

The terminal part 50 may be arranged on one side of the display area DA, for example, below the display area DA, and may include a plurality of terminals. The terminal part 50 may be exposed and electrically connected to a flexible printed circuit board, a driving integrated circuit (“IC”), or the like by not being covered by an insulating layer. A controller may be configured to change a plurality of image signals transferred from outside into a plurality of image data signals, and transfer the image data signals to the display area DA through the terminal part 50. The terminal part 50 may be configured to transfer data signals to the display area DA through a data line DL.

In addition, the controller may be configured to receive a vertical synchronization signal, a horizontal synchronization signal, and a clock signal, generate control signals for controlling driving of the driving circuit part 30, and transfer the control signals to the driving circuit part 30 through the terminal part 50. In addition, the controller may be configured to transfer a common voltage to the first common voltage line 13 and the second common voltage line 15.

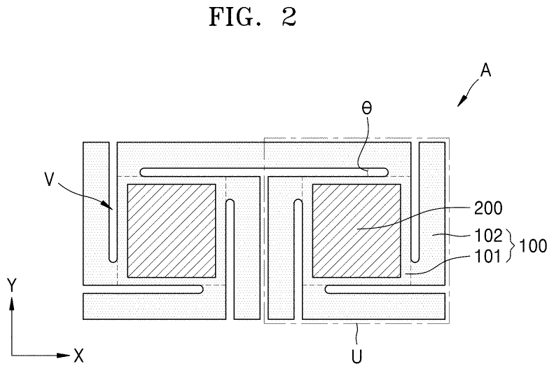

FIG. 2 is an enlarged schematic plan view of a region A of FIG. 1.

Referring to FIG. 2, the substrate 100 of the display apparatus 10 according to an embodiment may include a plurality of islands 101 apart from each other, a plurality of connectors 102 connecting the plurality of islands 101 to each other, and a plurality of through-portions V passing through the substrate 100. The plurality of through-portions V may be defined between the plurality of connectors 102 or between the plurality of islands 101 and the plurality of connectors 102.

The plurality of islands 101 may be apart from each other. As an example, the plurality of islands 101 may be repeatedly arranged in a first direction X and a second direction Y that is different from the first direction X to constitute a planar lattice pattern. As an example, the first direction X and the second direction Y may be orthogonal to each other. As another example, the first direction X and the second direction Y may form an obtuse angle or an acute angle.

A plurality of unit display parts 200 may be arranged on the plurality of islands 101, respectively. A unit display part 200 may include at least one display element that may implement a visible ray.

The plurality of connectors 102 may connect the plurality of islands 101 to each other. Specifically, four connectors 102 may be connected to each of the plurality of islands 101, and the four connectors 102 connected to one island 101 may extend in different directions to be adjacent to the island 101. Accordingly, the four connectors 102 may be connected to other islands 101 surrounding the island 101, respectively. At least some of the plurality of islands 101 and the plurality of connectors 102 may include the same material as each other and be formed continuously. The plurality of islands 101 and the plurality of connectors 102 may be formed as one body. The through-portion V may be arranged between the islands 101 and the connectors 102.

The through-portions V may pass through the substrate 100. The through-portions V may provide a separation region between the plurality of islands 101, reduce the weight of the substrate 100, and improve the flexibility of the substrate 100. In addition, when warping, bending, rolling, and the like occur to the substrate 100, the shapes of the through-portions V change and reduce stress from occurring while the substrate 100 transforms. Accordingly, abnormal transformation of the substrate 100 may be prevented and the durability of the substrate 100 may be improved. Through this, user convenience may be improved during use of the display apparatus 10, and particularly, the display apparatus 10 is easily applicable to wearable apparatuses.

The through-portions V may be formed by removing portions of the substrate 100 by using a method, such as etching. As another example, the substrate 100 may be formed to have the through-portions V while the substrate 100 is manufactured. An example of a process of forming the through-portions V in the substrate 100 may be various ones, and a method of manufacturing the through-portions V is not limited thereto.

Hereinafter, a unit part U, which is a basic unit forming the substrate 100, is set, and the structure of the substrate 100 is described in more detail based on this.

The unit part U may be repeatedly arranged in the first direction X and the second direction Y. That is, it may be understood that a plurality of unit parts U repeatedly arranged in the first direction X and the second direction Y are coupled to each other to constitute the substrate 100. The unit part U may include the island 101 and at least one connector 102 connected to the island 101. In an embodiment, four connectors 102 may be connected to one island 101.

The islands 101 of two adjacent unit parts U may be apart from each other, and the connectors 102 of two adjacent unit parts U may be connected to each other. Here, the connector 102 included in the unit part U may denote a partial region of the connector 102 in a region of the unit part U, or denote an entirety of the connector 102 connecting two islands 101 between the two adjacent islands 101.

The through-portion V, which is a vacant space, may be also arranged between the plurality of unit parts U. The through-portions V are regions formed by removing portions of the substrate 100, may improve the flexibility of the substrate 100, and reduce stress occurring while the substrate 100 transforms.

Among the plurality of unit parts U, two adjacent unit parts U may be symmetrical to each other. Specifically, as shown in FIG. 2, one unit part U may be symmetrical to the other unit part U arranged adjacent in the first direction X with respect to a symmetric axis parallel to the second direction Y and located between the two unit parts U.

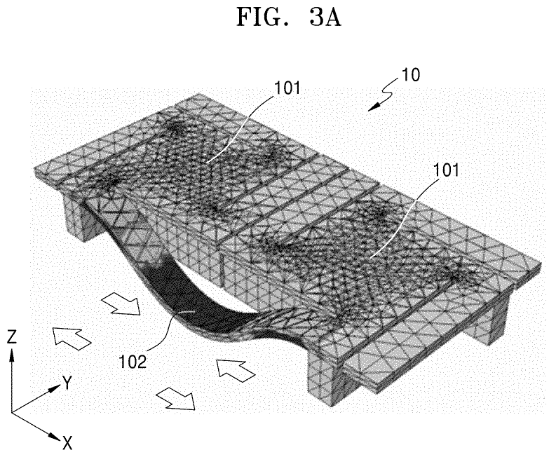

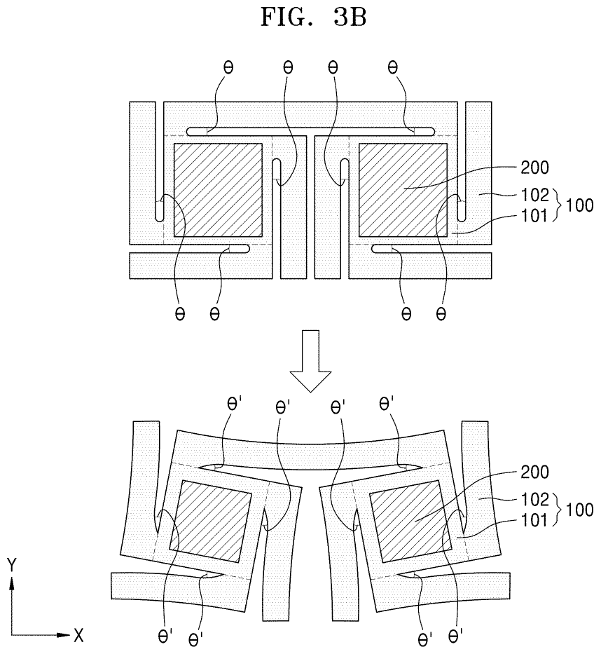

FIG. 3A shows one shape when the substrate 100 transforms.

Referring to FIG. 3A, when tensile force or contracting force is applied to the substrate 100, the connector 102 may bend, and a portion of the connector 102 may move in a third direction (a Z direction or a −Z direction). In this case, a distance between adjacent islands 101 may increase or decrease, and the shape of the display apparatus 10 may transform. As described above, because the connector 102 bends in the third direction, high stretchability of the display apparatus 10 may be secured. The stretching of the display apparatus 10 in the first direction X and the second direction Y may be performed independently.

FIG. 3B shows one shape when the substrate 100 transforms.

Referring to FIG. 3B, when external force is applied to the substrate 100, all angles formed by the lateral surfaces of the island 101, to which the connector 102 is connected, and the connector 102 increase (θ<θ′), and thus, the area of the through-portions V may increase. Accordingly, intervals between the islands 101 may increase, and the substrate 100 may stretch in the first direction X and the second direction Y, and the shape of the substrate 100 may change two-dimensionally or three-dimensionally.

Because the connector 102 has a smaller width than a width of the island 101, when external force is applied to the substrate 100, a shape change for the angle increase mainly appears in the connector 102, and the shape of the island 101 may not change while the substrate 100 is stretched. Accordingly, because the unit display part 200 arranged on the island 101 may be stably maintained even though the substrate 100 stretches, the display apparatus 10 is easily applicable to display apparatuses that require flexibility, for example, bendable display apparatuses, flexible display apparatuses, or stretchable display apparatuses.

Because stress concentrates on a connection portion of the connector 102 connected to the lateral surface of the island 101 while the substrate 100 stretches, the connection portion of the connector 102 may include a curved surface to prevent tearing and the like of the connector 102 due to the concentration of the stress.

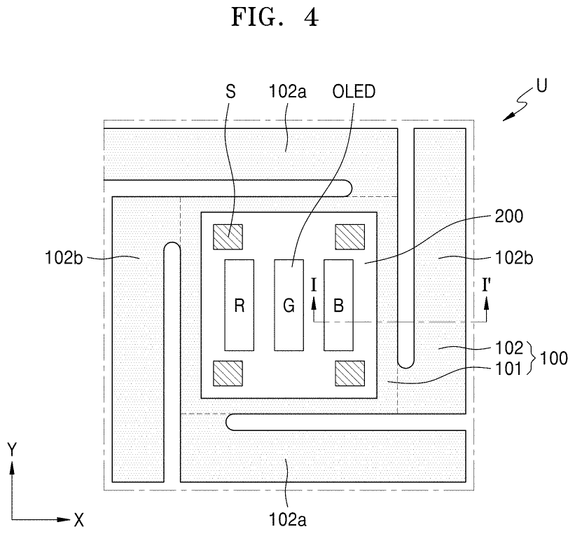

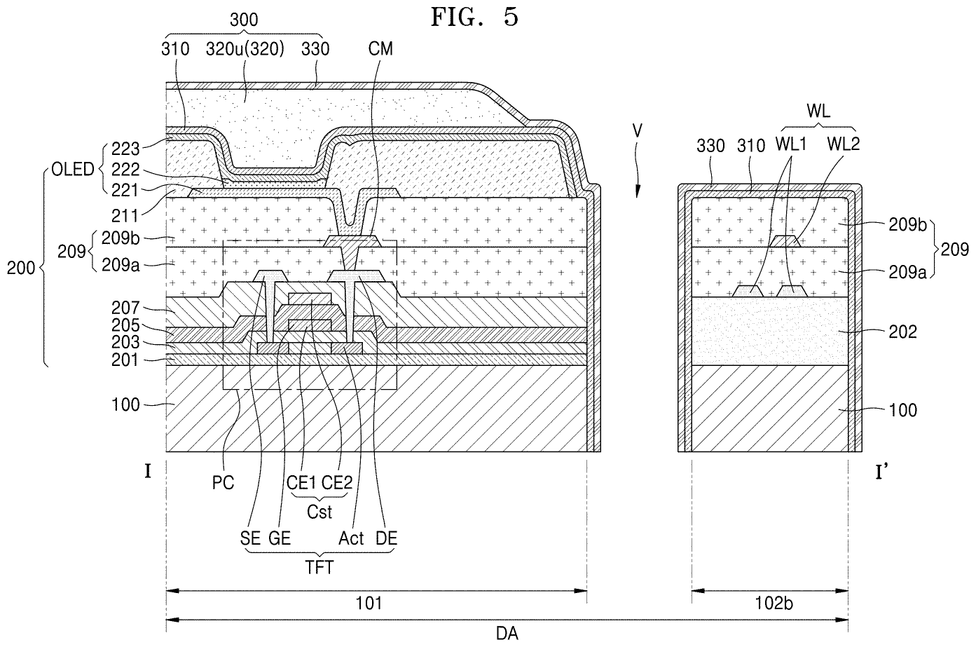

FIG. 4 is a schematic plan view of the unit part of FIG. 2, and FIG. 5 is a schematic cross-sectional view of an example of the unit part, taken along line I-I′ of FIG. 4. As used herein, the “plan view” is a view in the third direction (e.g., Z direction).

Referring to FIGS. 4 and 5, the unit display part 200 and an encapsulation layer 300 encapsulating the unit display part 200 may be located on the island 101 of the unit part U. The connector 102 may include a pair of (1-1)st connectors 102a and a pair of (1-2)nd connectors 102b, where the pair of (1-1)st connectors 102a are located on two opposite sides of the island 101, respectively, and each extend in a direction parallel to the first direction X, and the pair of (1-2)nd connectors 102b are located on two opposite sides of the island 101 and each extend in a direction parallel to the second direction Y.

The unit display part 200 may be located on the island 101. As an example, at least one organic light-emitting diode OLED that emits red, blue, green, or white light may be located on the unit display part 200. The organic light-emitting diode OLED may be electrically connected to the thin-film transistor TFT. In the present embodiment, the organic light-emitting diode OLED is described as the display element. However, the embodiment is not limited thereto, and the unit display part 200 may include various kinds of display elements, such as an inorganic light-emitting element, a quantum-dot light-emitting element, a liquid crystal element, and the like.

The unit display parts 200 may each include a plurality of organic light-emitting diodes OLED that emit different colors of light. As an example, as shown in the drawing, one unit display part 200 may include an organic light-emitting diode OLED that emits red light R, an organic light-emitting diode OLED that emits green light G, and an organic light-emitting diode OLED that emits blue light B to constitute one pixel.

However, the embodiment is not limited thereto. As another example, the unit display parts 200 may each include one organic light-emitting diode OLED that emits red, blue, green, or white light, and each unit display part 200 may form a sub-pixel. As another example, the unit display part 200 may include a plurality of pixels.

In addition, the configurations of the organic light-emitting diodes OLED inside the unit display part 200 may form various configurations, such as an RGB configuration, a pentile structure, a honeycomb structure, and the like, according to the efficiency of a material included in an organic emission layer.

A spacer S may be formed around the unit display part 200. The spacer S is a member for preventing mask chopping, and the height of the spacer S from the upper surface of the substrate 100 may be greater than the height of the organic light-emitting diode OLED. Though it is shown in FIG. 4 that the spacer S is provided in an outer region, which is the periphery of the unit display part 200, the embodiment is not limited thereto. For example, the spacer S may be arranged inside the unit display part 200. As an example, the spacer S may be provided on a pixel-defining layer 211 formed in the unit display part 200.

Referring to FIG. 5, the display apparatus 10 according to an embodiment includes the substrate 100, the unit display part 200 including a planarization layer 209, and the encapsulation layer 300 encapsulating each of the unit display parts 200. The unit display part 200 may be arranged on the island 101 of the substrate 100, and wirings WL may be arranged on the (1-2)nd connector 102b connecting the islands 101 to each other.

First, the unit display part 200 and the encapsulation layer 300 arranged on the island 101 are described according to a stacking order.

A buffer layer 201 may be formed on the island 101, where the buffer layer 201 is formed to prevent impurities from penetrating a semiconductor layer Act of the thin-film transistor TFT. The buffer layer 201 may include an inorganic insulating material, such as silicon nitride, silicon oxynitride, and silicon oxide, and include a single layer or a multi-layer including the above inorganic insulating materials.

A pixel circuit PC may be disposed on the buffer layer 201. The pixel circuit PC includes the thin-film transistor TFT and a storage capacitor Cst. The thin-film transistor TFT may include the semiconductor layer Act, a gate electrode GE, a source electrode SE, and a drain electrode DE. In the present embodiment, though a top-gate type thin-film transistor in which the gate electrode GE is disposed over the semiconductor layer Act with a gate insulating layer 203 therebetween is shown, the thin-film transistor TFT may be a bottom-gate type thin-film transistor in another embodiment.

The semiconductor layer Act may include polycrystalline silicon. Alternatively, the semiconductor layer Act may include amorphous silicon, an oxide semiconductor, or an organic semiconductor. The gate electrode GE may include a low-resistance metal material. The gate electrode GE may include a conductive material including molybdenum (Mo), aluminum (Al), copper (Cu), and titanium (Ti) and have a single-layered structure or a multi-layered structure including the above materials.

The gate insulating layer 203 between the semiconductor layer Act and the gate electrode GE may include an inorganic insulating material including silicon oxide, silicon nitride, silicon oxynitride, aluminum oxide, titanium oxide, tantalum oxide, hafnium oxide, and the like. The gate insulating layer 203 may include a single layer or a multi-layer including the above materials.

The source electrode SE and the drain electrode DE may each include a material having high conductivity. The source electrode SE and the drain electrode DE may each include a conductive material including molybdenum (Mo), aluminum (Al), copper (Cu), and titanium (Ti) and include a single layer or a multi-layer including the above materials. In an embodiment, the source electrode SE and the drain electrode DE may each include a multi-layer of Ti/Al/Ti.

The storage capacitor Cst may include a lower electrode CE1 and an upper electrode CE2 overlapping each other in a plan view with a first interlayer-insulating layer 205 therebetween. The storage capacitor Cst may overlap the thin-film transistor TFT. With regard to this, it is shown in FIG. 5 that the gate electrode GE of the thin-film transistor TFT serves as the lower electrode CE1 of the storage capacitor Cst. In another embodiment, the storage capacitor Cst may not overlap the thin-film transistor TFT in a plan view. The storage capacitor Cst may be covered by a second interlayer-insulating layer 207.

The first and second interlayer-insulating layers 205 and 207 may each include an inorganic insulating material including silicon oxide, silicon nitride, silicon oxynitride, aluminum oxide, titanium oxide, tantalum oxide, hafnium oxide, and the like. The first and second interlayer-insulating layers 205 and 207 may each include a single layer or a multi-layer including the above materials.

The pixel circuit PC including the thin-film transistor TFT and the storage capacitor Cst may be covered by the planarization layer 209.

The planarization layer 209 may include an organic insulating material including a general-purpose polymer, such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof. In an embodiment, the planarization layer 209 may include PI.

In another embodiment, the planarization layer 209 may include an inorganic insulating material including silicon oxide, silicon nitride, silicon oxynitride, aluminum oxide, titanium oxide, tantalum oxide, hafnium oxide, and the like.

In an embodiment, the planarization layer 209 may have a structure in which a first insulating layer 209a and a second insulating layer 209b are stacked. In this case, both the first insulating layer 209a and the second insulating layer 209b may be organic insulating materials or inorganic insulating materials. Alternatively, one of the first insulating layer 209a and the second insulating layer 209b may be an organic insulating material, and the other may be an inorganic insulating material. However, various modifications may be made.

Because the planarization layer 209 has a structure in which the first insulating layer 209a and the second insulating layer 209b are stacked, a conductive layer such as a connection electrode CM and a second wiring WL2 may be disposed between the first insulating layer 209a and the second insulating layer 209b, and thus, high integration may be implemented.

The connection electrode CM may be disposed on the first insulating layer 209a, and connected to the drain electrode DE of the thin-film transistor TFT through a contact hole defined in the first insulating layer 209a. The connection electrode CM may be connected to the organic light-emitting diode OLED disposed on the second insulating layer 209b and may serve as a medium connecting the organic light-emitting diode OLED to the thin-film transistor TFT.

The pixel electrode 221 may be disposed on the planarization layer 209. The pixel electrode 221 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 221 may further include a layer on/under the reflective layer, the layer including ITO, IZO, ZnO, or In₂O₃. The pixel electrode 221 may be connected to the connection electrode CM through a contact hole defined in the second insulating layer 209b.

The pixel-defining layer 211 may be formed on the pixel electrode 221. The pixel-defining layer 211 may include an opening that exposes the upper surface of the pixel electrode 221, and cover the edges of the pixel electrode 221. Accordingly, the pixel-defining layer 211 may define an emission area of the pixel. The pixel-defining layer 211 may include an organic insulating material. Alternatively, the pixel-defining layer 211 may include an inorganic insulating material, such as silicon nitride (SiNₓ), silicon oxynitride (SiON), or silicon oxide (SiOₓ). Alternatively, the pixel-defining layer 211 may include an organic insulating material and an inorganic insulating material.

An intermediate layer 222 of the organic light-emitting diode OLED may include a low-molecular weight material or a polymer material. In the case where the intermediate layer 222 includes a low molecular weight material, the intermediate layer 222 may have a structure in which a hole injection layer (“HIL”), a hole transport layer (“HTL”), an emission layer (“EML”), an electron transport layer (“ETL”), an electron injection layer (“EIL”), etc. are stacked in a single or composite configuration. The intermediate layer 222 may include various organic materials, such as copper phthalocyanine (CuPc), N,N′-Di(naphthalene-1-yl)-N,N′-diphenyl-benzidine (“NPB”), and tris-8-hydroxyquinoline aluminum (Alq3). These layers may be formed by vacuum deposition.

In the case where the intermediate layer 222 includes a polymer material, the intermediate layer 222 may have a structure including an HTL and an EML. In this case, the HTL may include poly(3,4-ethylenedioxythiophene) (“PEDOT”), and the EML may include a polymer material, such as a polyphenylene vinylene (“PPV”)-based material and a polyfluorene-based material. The intermediate layer 222 may be formed by screen printing, inkjet printing, laser induced thermal imaging (“LITI”), or the like.

However, the intermediate layer 222 is not necessarily limited thereto and may have other structures. The intermediate layer 222 may include a layer as one body over the plurality of pixel electrodes 221, or include a layer patterned to correspond to each of the plurality of pixel electrodes 221.

An opposite electrode 223 may include a conductive material having a low work function. As an example, the opposite electrode 223 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the opposite electrode 223 may further include a layer on the (semi) transparent layer, the layer including ITO, IZO, ZnO, or In₂O₃. The opposite electrode 223 may be formed in not only the display area DA but also in a first non-display area NDA1. The intermediate layer 222 and the opposite electrode 223 may be formed by thermal deposition.

A capping layer (not shown) for protecting the opposite electrode 223 may be further disposed on the opposite electrode 223. The capping layer may include lithium fluoride (LiF), an inorganic material, and/or an organic material.

The encapsulation layer 300 encapsulating the unit display part 200 is formed on the opposite electrode 223. The encapsulation layer 300 may block external oxygen and moisture and include a single layer or a plurality of layers. The encapsulation layer 300 may include at least one of an organic encapsulation layer and an inorganic encapsulation layer.

Though it is shown in FIG. 4 that the encapsulation layer 300 includes first and second inorganic encapsulation layers 310 and 330, and an organic encapsulation layer 320 therebetween, the embodiment is not limited thereto. In another embodiment, the number of organic encapsulation layers, the number of inorganic encapsulation layers, and a stacking order may be changed.

The first and second inorganic encapsulation layers 310 and 330 may each include at least one inorganic insulating material among aluminum oxide, titanium oxide, tantalum oxide, hafnium oxide, zinc oxide, silicon oxide, silicon nitride, silicon oxynitride, and the like, and be formed by chemical vapor deposition (“CVD”). The organic encapsulation layer 320 may include a polymer-based material. The polymer-based material may include an acryl-based resin, an epoxy-based resin, PI, and polyethylene.

Because the first inorganic encapsulation layer 310 is formed along a structure thereunder, the upper surface of the first inorganic encapsulation layer 310 is not flat, as shown in FIG. 5. The organic encapsulation layer 320 may cover the first inorganic encapsulation layer 310 and, unlike the first inorganic encapsulation layer 310, an upper surface of the organic encapsulation layer 320 may be approximately flat. Specifically, the upper surface of a portion of the organic encapsulation layer 320 that corresponds to the organic light-emitting diode OLED, which is the display element, may be approximately flat. In addition, the organic encapsulation layer 320 may alleviate stress occurring to the first and second inorganic encapsulation layers 310 and 330.

The organic encapsulation layer 320 may include at least one of PMMA, polycarbonate (“PC”), PS, an acryl-based resin, an epoxy-based resin, PI, polyethylene, polyethylene sulfonate, polyoxymethylene, polyarylate, hexamethyldisiloxane, and the like.

In the present embodiment, the organic encapsulation layer 320 may include unit organic encapsulation layers 320u to correspond to the unit display parts 200, respectively. That is, the unit organic encapsulation layer 320u may be disposed on the island 101 of the substrate 100, and may not be arranged on the connector 102. Accordingly, the first and second inorganic encapsulation layers 310 and 330 contact each other outside the unit organic encapsulation layer 320u, and thus, may capsulate each unit display part 200 individually.

Because the encapsulation layer 300 includes the first inorganic encapsulation layer 310, the organic encapsulation layer 320, and the second inorganic encapsulation layer 330, even when cracks occur inside the encapsulation layer 300, the cracks may not be connected between the first inorganic encapsulation layer 310 and the organic encapsulation layer 320 or between the organic encapsulation layer 320 and the second inorganic encapsulation layer 330 through the above multi-layered structure. With this configuration, forming of a path through which external moisture or oxygen penetrates the unit display part 200 may be prevented or reduced. In addition, because the second inorganic encapsulation layer 330 contacts the first inorganic encapsulation layer 310 at the edge outside the unit organic encapsulation layer 320u, the unit organic encapsulation layer 320u may not be exposed to outside.

Because the first and second inorganic encapsulation layers 310 and 330 may be formed over the entire surface of the substrate 100 by CVD, the first and second inorganic encapsulation layers 310 and 330 may be formed to cover the lateral surface of the through-portion V.

When forming the unit organic encapsulation layer 320u, a preset amount of liquid organic material is coated to correspond to the unit display part 200, and then hardened. In this case, due to characteristics of the liquid organic material, a flow occurs in an edge direction of the unit display part 200. To prevent this, a dam structure (not shown) and/or an indented recess structure (not shown) may be further provided to the edge of the unit display part 200.

The wirings WL configured to supply various kinds of signals and/or voltages to the unit display part 200 may be arranged on the connector 102b of the substrate 100. The wirings WL may include a first wiring WL1 and a second wiring WL2. The first wiring WL1 may include the same material as that of the source electrode SE or the drain electrode DE of the thin-film transistor TFT. Alternatively, the first wiring WL1 disposed on an organic material layer 202 may include the same material as that of the gate electrode GE of the thin-film transistor TFT. The second wiring WL2 may be disposed on a different layer from the first wiring WL1. The second wiring WL2 may be disposed on the first insulating layer 209a. The second wiring WL2 may include the same material as that of the connection electrode CM. The second wiring WL2 may overlap at least a portion of the first wiring WL1 in a plan view. The first wiring WL1 and the second wiring WL2 may be provided in plurality on the central portion of the connector 102b and apart from each other.

The second wiring WL2 may be covered by the second insulating layer 209b. The first inorganic encapsulation layer 310 and the second inorganic encapsulation layer 330 may be stacked on the second insulating layer 209b. Because the first inorganic encapsulation layer 310 and the second inorganic encapsulation layer 330 are formed by using an open mask after the through-portion V is formed, the first inorganic encapsulation layer 310 and the second inorganic encapsulation layer 330 may surround the lateral surface of the through-portion V. Though not shown in the drawing, the pixel-defining layer 211 may be further disposed between the second insulating layer 209b and the first inorganic encapsulation layer 310.

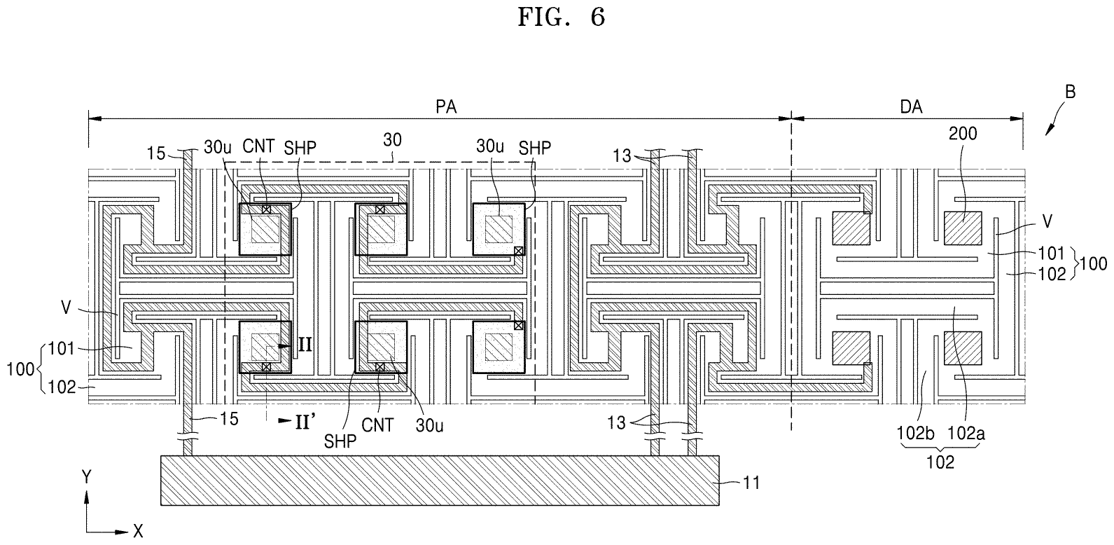

FIG. 6 is a schematic plan view of a region B of FIG. 1 according to an embodiment.

Referring to FIG. 6, the unit display part 200 is arranged in the display area DA. A unit driving circuit part 30u and a shield part SHP overlapping the unit driving circuit part 30u may be arranged in the peripheral area PA.

In the display apparatus 10 according to an embodiment, the shape of the substrate 100 in the peripheral area PA may be the same as the shape of the substrate 100 in the display area DA.

The island 101, the connector 102, and the through-portion V arranged in the display area DA may be referred to as a first island, a first connector, and a first through-portion, respectively, and the island 101, the connector 102, and the through-portion V arranged in the peripheral area PA may be referred to as a second island, a second connector, and a second through-portion, respectively. In this case, the shapes of the first island, the first connector, and the first through-portion may be the same as the shapes of the second island, the second connector, and the second through-portion, respectively.

That is, in the peripheral area PA, the substrate 100 may include the connectors 102 connecting the plurality of islands 101 to other plurality of islands 101. The connector 102 may include a pair of (1-1)st connectors 102a and a pair of (1-2)nd connectors 102b, where the pair of (1-1)st connectors 102a are located on two opposite sides of the island 101 and each extend in a direction parallel to the first direction X, and the pair of (1-2)nd connectors 102b are located on two opposite sides of the island 101 and each extend in a direction parallel to the second direction Y.

The driving circuit part 30 (see FIG. 1) is arranged in one region of the peripheral area PA, and the driving circuit part 30 may include a plurality of unit driving circuit parts 30u. The plurality of unit driving circuit parts 30u may each be arranged on one island 101.

The unit driving circuit part 30u may be located on a portion of the island 101 arranged in the peripheral area PA, and may include at least one thin-film transistor TFTd. The unit driving circuit part 30u may be configured to generate scan signals, emission control signals, and the like, and transfer the same to the display area DA.

The shield part SHP overlapping the unit driving circuit part 30u in a plan view may be disposed on the unit driving circuit part 30u. The shield part SHP may be disposed for each unit driving circuit part 30u. Accordingly, the shield part SHP may be provided in plurality, and the plurality of shield parts SHP may be apart from each other to correspond to the driving circuit part 30. The shield part SHP may include a conductive material and protect the driving circuit part 30 such that the driving circuit part 30 is not damaged by electrostatic discharge. The shield part SHP may be connected to the second common voltage line 15 and may receive a common voltage, which is a low-potential constant voltage.

The first common voltage line 13 and the second common voltage line 15 may be arranged on two opposite sides of the driving circuit part 30, respectively. The first common voltage line 13 may be adjacent to the display area DA, and the second common voltage line 15 may be adjacent to the edge of the display apparatus 10.

The first common voltage line 13 may be configured to provide a low potential constant voltage to a light-emitting element in the display area DA. The first common voltage line 13 may extend in the Y direction mostly and wind along the shape of the island 101 and the connector 102 of the substrate 100. That is, a main portion of the first common voltage line 13 may extend in the Y direction across the plurality of islands and connectors 102. A portion of the first common voltage line 13 may branch off in the X direction and extend to the display area DA. In an embodiment, the first common voltage line 13 may be connected to the plurality of unit display parts 200.

The second common voltage line 15 may be configured to provide a low-potential constant voltage to the shield part SHP. The second common voltage line 15 may extend in the Y direction mostly and wind along the shape of the island 101 and the connector 102 of the substrate 100. That is, a main portion of the second common voltage line 15 may extend in the Y direction across the plurality of islands and connectors 102. A portion of the second common voltage line 15 may branch off in the X direction and extend to the driving circuit part 30.

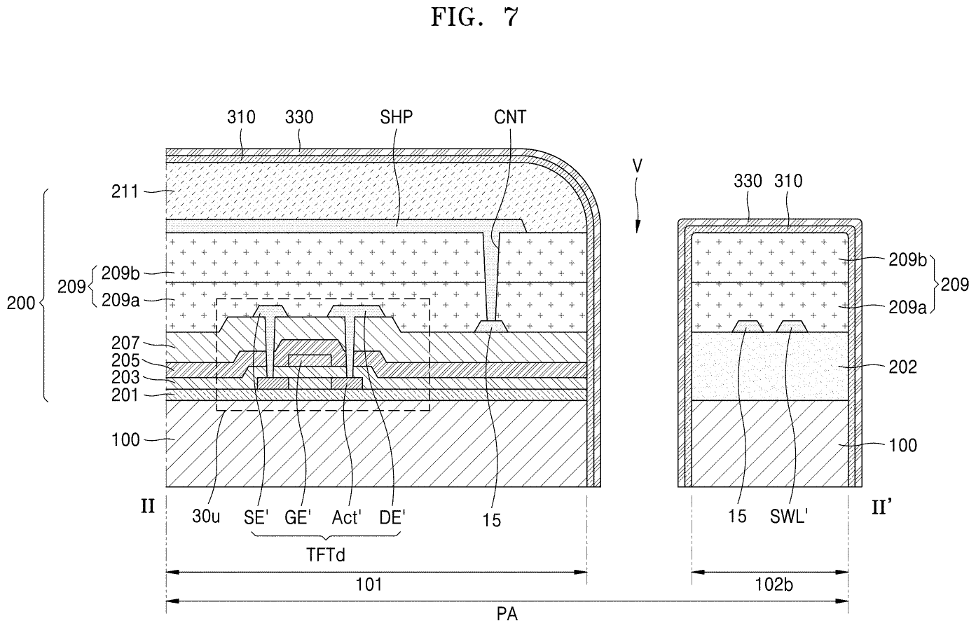

FIG. 7 is a schematic cross-sectional view of an example of the region B, taken along line II-II′ of FIG. 6. In FIG. 7, the same reference numerals as those of FIG. 5 denote the same members, and thus, repeated descriptions thereof are omitted.

Referring to FIG. 7, the unit driving circuit part 30u may be included in the island 101 arranged in the peripheral area PA. The unit driving circuit part 30u may include at least one thin-film transistor TFTd. In addition, the unit driving circuit part 30u may include a storage capacitor (not shown).

The thin-film transistor TFTd may include a semiconductor layer Act′, a gate electrode GE′, a source electrode SE′, and a drain electrode DE′. In the present embodiment, though a top-gate type thin-film transistor in which the gate electrode GE′ is disposed on the semiconductor layer Act′ with a gate insulating layer 203 therebetween is shown, the thin-film transistor TFTd may be a bottom-gate type thin-film transistor in another embodiment.

The semiconductor layer Act′ may include polycrystalline silicon. Alternatively, the semiconductor layer Act′ may include amorphous silicon, an oxide semiconductor, or an organic semiconductor. The gate electrode GE′ may include a low-resistance metal material. The gate electrode GE′ may include a conductive material including molybdenum (Mo), aluminum (Al), copper (Cu), and titanium (Ti) and have a single-layered structure or a multi-layered structure including the above materials. The gate electrode GE′ overlaps the semiconductor layer Act′ in a plan view, and the gate insulating layer 203 is disposed between the gate electrode GE′ and the semiconductor layer Act′.

The source electrode SE′ and the drain electrode DE′ may be disposed on the second interlayer-insulating layer 207. The source electrode SE′ and the drain electrode DE′ may each include a material having high conductivity. The source electrode SE′ and the drain electrode DE′ may each include a conductive material including molybdenum (Mo), aluminum (Al), copper (Cu), and titanium (Ti) and include a single layer or a multi-layer including the above materials. In an embodiment, the source electrode SE′ and the drain electrode DE′ may each include a multi-layer of Ti/Al/Ti.

In the present embodiment, the second common voltage line 15 may be disposed on the second interlayer-insulating layer 207. In an embodiment, the second common voltage line 15 may include the same material as that of the source electrode SE′ and the drain electrode DE′, and be arranged on the same layer as the source electrode SE′ and the drain electrode DE′. The second common voltage line 15 may include a conductive material including molybdenum (Mo), aluminum (Al), copper (Cu), and titanium (Ti) and have a single-layered structure or a multi-layered structure including the above materials.

The unit driving circuit part 30u and the second common voltage line 15 may be covered by the planarization layer 209, and the planarization layer 209 may include the first insulating layer 209a and the second insulating layer 209b that are stacked.

The shield part SHP overlapping the unit driving circuit part 30u in a plan view may be disposed on the planarization layer 209. The shield part SHP may be disposed on the same layer as the pixel electrode 221 (see FIG. 5) and may include the same material as that of the pixel electrode 221. The shield part SHP may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the shield part SHP may include silver (Ag), magnesium (Mg), aluminum (Al), platinum (Pt), palladium (Pd), gold (Au), nickel (Ni), neodymium (Nd), iridium (Ir), chrome (Cr), or a compound thereof.

The shield part SHP may be connected to the second common voltage line 15 through a contact hole CNT defined in the planarization layer 209. The contact hole CNT may pass through the second insulating layer 209b and the first insulating layer 209a. In an embodiment, the contact hole CNT may be arranged on the island 101. However, the embodiment is not limited thereto. In another embodiment, the contact hole CNT may be formed on the (1-2)nd connector 102b.

Because the shield part SHP is electrically connected to the second common voltage line 15, the shield part SHP may receive a constant voltage. Accordingly, the shield part SHP may protect the unit driving circuit part 30u from external signals or electrostatic discharge.

An insulating layer such as the pixel-defining layer 211 may be disposed on the shield part SHP, and the first inorganic encapsulation layer 310 and the second inorganic encapsulation layer 330 may be stacked on the pixel-defining layer 211. In an embodiment, the pixel-defining layer 211 disposed on the shield part SHP may be omitted.

The second common voltage line 15 and a signal wiring SWL′ may be arranged on the (1-2)nd connector 102b of the substrate 100. The second common voltage line 15 may be configured to provide a low-potential constant voltage, and the signal wiring SWL′ may be configured to provide scan signals, emission control signals, and the like to the display area DA.

The second common voltage line 15 and the signal wiring SWL′ may be disposed on the organic material layer 202. The second common voltage line 15 may be continuously arranged on the (1-2)nd connector 102b and the island 101. The signal wiring SWL′ may be continuously arranged on the (1-2)nd connector 102b and the island 101. Alternatively, the signal wiring SWL′ may be connected to a wiring (not shown) on the island 101 through a contact hole, where the wiring is disposed on the same layer as the gate electrode GE′. The signal wiring SWL′ may be provided in plurality.

The second common voltage line 15 and the signal wiring SWL′ may be covered by the planarization layer 209. The first inorganic encapsulation layer 310 and the second inorganic encapsulation layer 330 may be stacked on the planarization layer 209. The first inorganic encapsulation layer 310 and the second inorganic encapsulation layer 330 may surround the lateral surface of the through-portion V. Though not shown in the drawing, the pixel-defining layer 211 may be further arranged between the planarization layer 209 and the opposite electrode 223.

Though it is shown in FIG. 7 that the second common voltage line 15 is disposed on the second interlayer-insulating layer 207, the embodiment is not limited thereto.

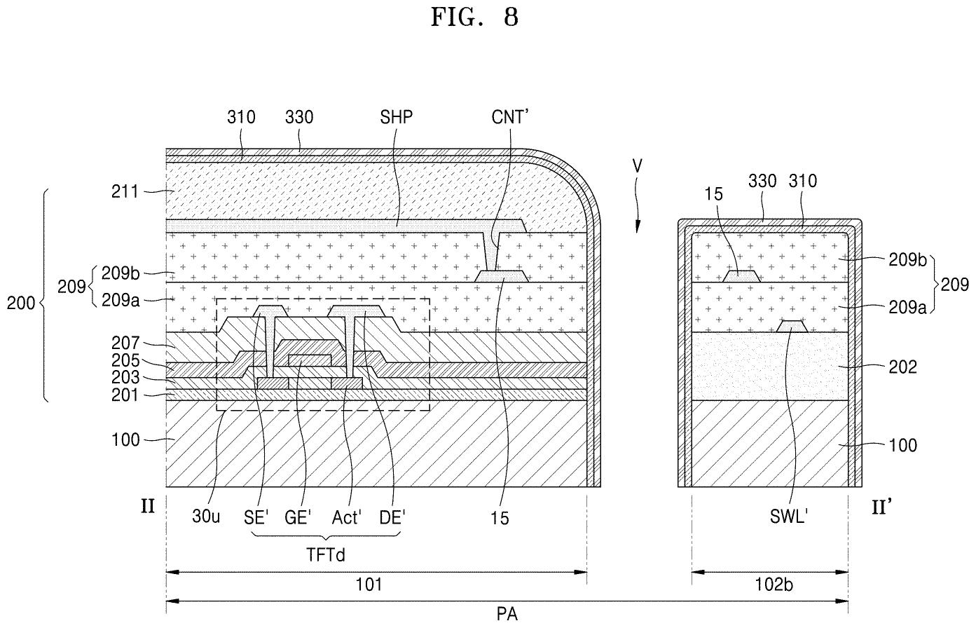

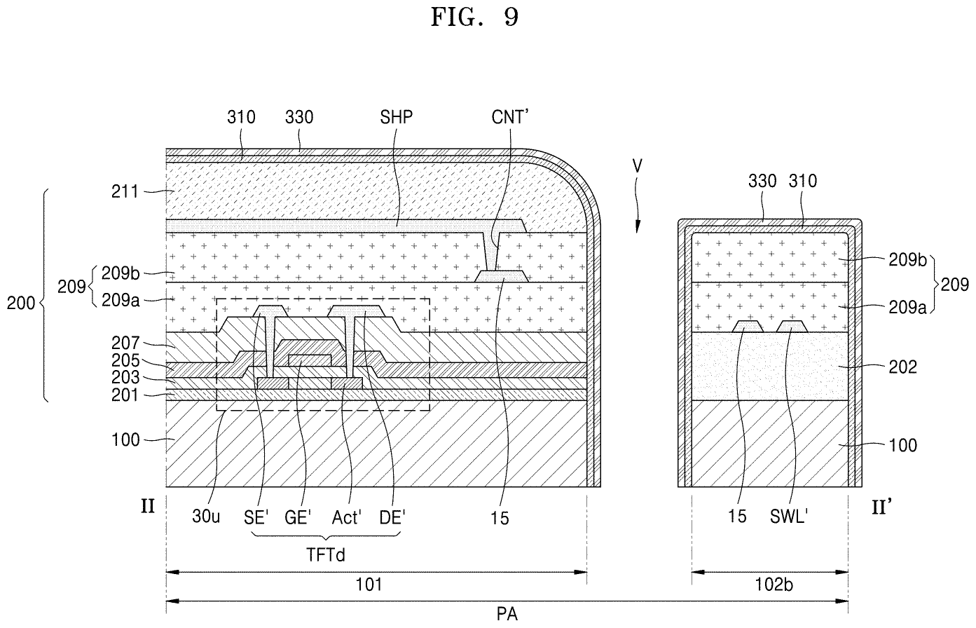

FIGS. 8 to 10 are schematic cross-sectional views of examples of the region B, taken along line II-II′ of FIG. 6. In FIGS. 8 and 9, the same reference numerals as those of FIG. 7 denote the same members, and thus, repeated descriptions thereof are omitted.

Referring to FIG. 8, the second common voltage line 15 may be disposed on the first insulating layer 209a. The second common voltage line 15 may include a conductive material including molybdenum (Mo), aluminum (Al), copper (Cu), and titanium (Ti) and have a single-layered structure or a multi-layered structure including the above materials. The shield part SHP may be connected to the second common voltage line 15 through a contact hole CNT′ defined in the second insulating layer 209b.

In FIG. 8, the second common voltage line 15 may be disposed on the first insulating layer 209a on both the island 101 and the (1-2)nd connector 102b. However, the embodiment is not limited thereto.

As shown in FIG. 9, the second common voltage line 15 may be disposed on the first insulating layer 209a on the island 101, and be disposed on the organic material layer 202, which is a layer under the first insulating layer 209a, on the (1-2)nd connector 102b. Alternatively, unlike the drawings, the second common voltage line 15 may be disposed under the first insulating layer 209a on the island 101, and be disposed on the first insulating layer 209a on the (1-2)nd connector 102b. In this case, the second common voltage line 15 is not continuously arranged on the island 101 and the (1-2)nd connector 102b, but the second common voltage line 15 arranged on the island 101 may be connected to the second common voltage line 15 continuously arranged on the (1-2)nd connector 102b through a contact hole.

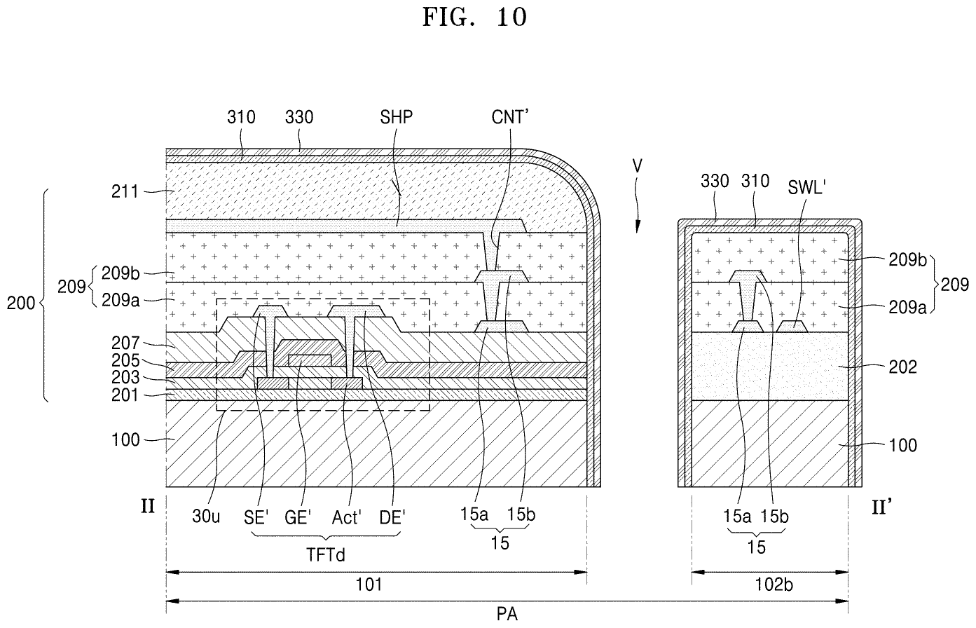

Referring to FIG. 10, the second common voltage line 15 may include a lower layer 15a and an upper layer 15b disposed on different layers. The first insulating layer 209a may be disposed between the lower layer 15a and the upper layer 15b. The upper layer 15b may be connected to the lower layer 15a through a contact hole defined in the first insulating layer 209a.

The lower layer 15a and the upper layer 15b may each include a conductive material including molybdenum (Mo), aluminum (Al), copper (Cu), and titanium (Ti) and have a single-layered structure or a multi-layered structure including the above materials.

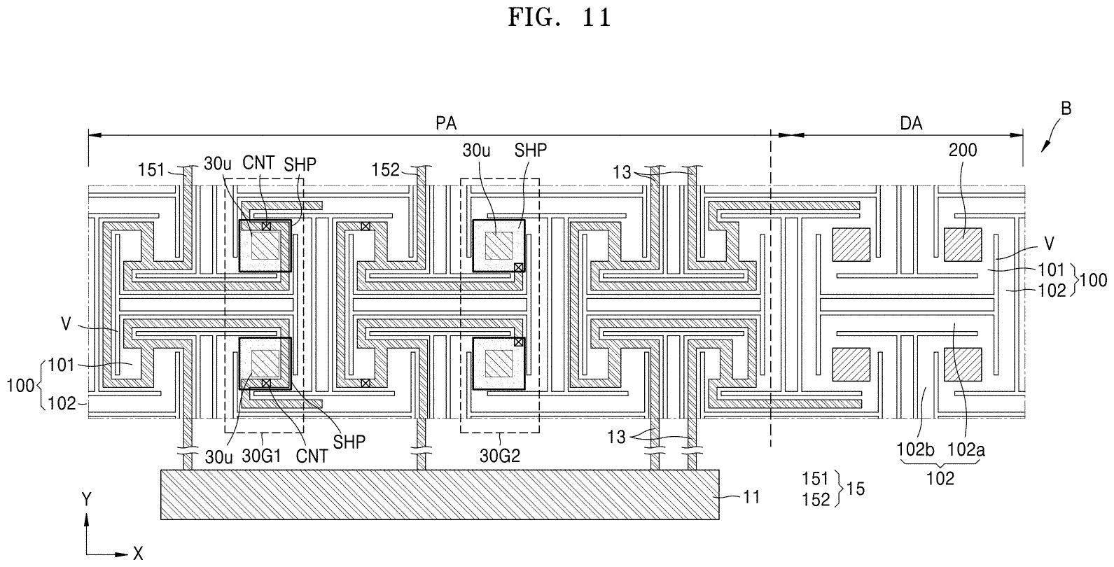

FIG. 11 is a schematic plan view of a region B of FIG. 1 according to another embodiment. In FIG. 11, the same reference numerals as those of FIG. 6 denote the same members, and thus, repeated descriptions thereof are omitted.

Referring to FIG. 11, the second common voltage line 15 may be provided in plurality. As an example, the second common voltage line 15 may include a (2-1)st common voltage line 151 and a (2-2)nd common voltage line 152. The (2-1)st common voltage line 151 and the (2-2)nd common voltage line 152 may branch off from the main common voltage line 11 and extend in the Y direction. The (2-1)st common voltage line 151 and the (2-2)nd common voltage line 152 may extend in the Y direction mostly, but wind along the shape of the island 101 and the connector 102.

The shield part SHP overlapping the unit driving circuit part 30u in a plan view may be disposed on the unit driving circuit part 30u. The shield part SHP may be disposed for each unit driving circuit part 30u. Accordingly, the shield part SHP may be provided in plurality, and the plurality of shield parts SHP may be apart from each other to correspond to the driving circuit part 30. The shield part SHP may include a conductive material and protect the driving circuit part 30 such that the driving circuit part 30 is not damaged by electrostatic discharge. The shield part SHP may be connected to the second common voltage line 15 and may receive a common voltage, which is a low-potential constant voltage.

One of the plurality of second common voltage lines 15 may be disposed between the unit driving circuit parts 30u. As an example, the unit driving circuit parts 30u may be disposed on two opposite sides of the (2-2)nd common voltage line 152. The unit driving circuit parts 30u may be divided into a plurality of groups. As an example, the unit driving circuit parts 30u may be divided into a first driving circuit group 30G1 and a second driving circuit group 30G2. The unit driving circuit parts 30u included in each group may be arranged in a line in the Y direction. In this case, the (2-1)st common voltage line 151 may be configured to apply a voltage to the shield part SHP that shields the unit driving circuit part 30u belonging to a first driving circuit group 30G1, and the (2-2)nd common voltage line 152 may be configured to apply a voltage to the shield part SHP that shields the unit driving circuit part 30u belonging to a second driving circuit group 30G2. One of the first driving circuit group 30G1 and the second driving circuit group 30G2 may be configured to provide scan signals, and the other may be configured to provide emission control signals.

Though the case where the unit driving circuit parts 30u are divided into two groups has been shown in the drawing, the embodiment is not limited thereto. The unit driving circuit parts 30u may be divided into three or more groups. In this case, one of the plurality of second common voltage lines 15 may be arranged between the groups of the unit driving circuit parts 30u.

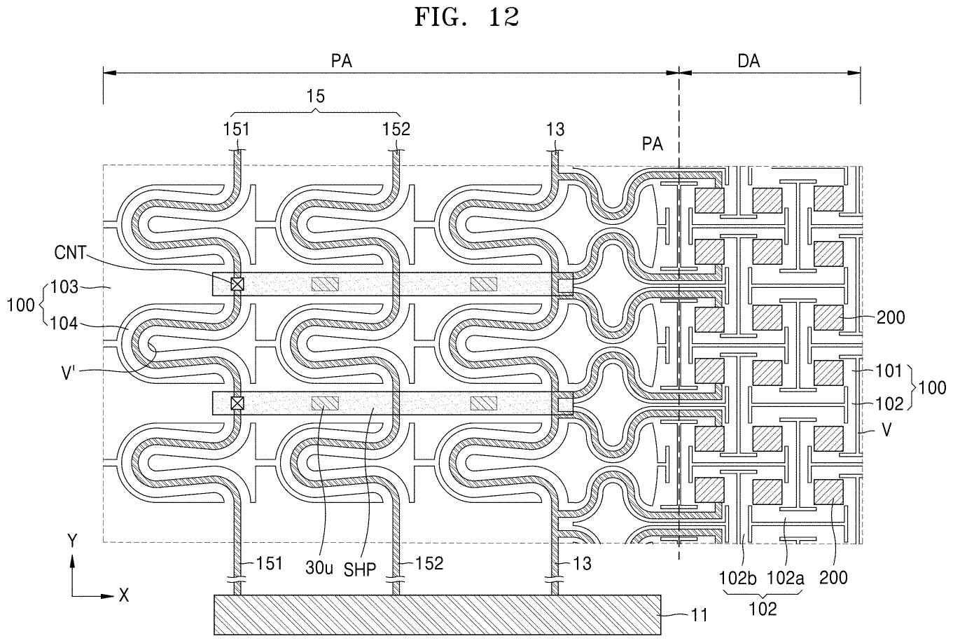

FIG. 12 is a schematic plan view of a region B of FIG. 1 according to still another embodiment. In FIG. 12, the same reference numerals as those of FIG. 6 denote the same members, and thus, repeated descriptions thereof are omitted.

Referring to FIG. 12, the unit display part 200 is arranged in the display area DA, and a unit driving circuit part 30u and a shield part SHP overlapping the unit driving circuit part 30u may be arranged in the peripheral area PA.

In the display apparatus according to an embodiment, the shape of the substrate 100 in the peripheral area PA may be different from the shape of the substrate 100 in the display area DA.

In the display area DA, the substrate 100 may include a plurality of first islands 101, a first connector 102, and a first through-portion V. The first connector 102 may connect the plurality of first islands 101, and the first through-portion V may be arranged between the plurality of first islands 101. The first connector 102 may include a pair of (1-1)st connectors 102a and a pair of (1-2)nd connectors 102b, where the pair of (1-1)st connectors 102a are located on two opposite sides of the first island 101 and each extend in a direction parallel to the first direction X, and the pair of (1-2)nd connectors 102b are located on two opposite sides of the first island 101 and each extend in a direction parallel to the second direction Y.

In the peripheral area PA, the substrate 100 may include a plurality of second islands 103, a second connector 104, and a second through-portion V′. The plurality of second islands 103 may extend in a −X direction from the display area DA and be apart from each other in the Y direction.

The second connector 104 may connect the second islands 103 adjacent to each other. The second connector 104 may be bent and may extend to have a winding shape. As an example, the second connector 104 may have a shape in which ‘S’ is connected. Because the second connector 104 has a winding shape, in the case where external force is applied to the peripheral area PA, the second connector 104 may be easily stretched or contracted, and the peripheral area PA may be stretched.

The second through-portion V may be arranged between the second islands 103, between the second connectors 104, and between the second island 103 and the second connector 104.

As described above, the second island 103, the second connector 104, and the second through-portion V may have shapes different from the shapes of the first island 101, the first connector 102, and the first through-portion V, respectively.

In the present embodiment, the plurality of unit driving circuit parts 30u may be arranged on one second island 103. The plurality of unit driving circuit parts 30u may be arranged in a line in the X direction. The unit driving circuit part 30u may be configured to generate scan signals, emission control signals, and the like and transfer the same to the display area DA.

The plurality of shield parts SHP may be arranged in the peripheral area PA. The plurality of shield parts SHP may correspond to the second island 103 and be apart from each other. In the present embodiment, one shield part SHP may overlap the plurality of unit driving circuit parts 30u in a plan view. The shield part SHP may include a conductive material and protect the driving circuit part 30 such that the driving circuit part 30 is not damaged by electrostatic discharge. The shield part SHP may be connected to the second common voltage line 15 and may receive a common voltage, which is a low-potential constant voltage.

The first common voltage line 13 and the second common voltage line 15 may be arranged on two opposite sides of the driving circuit part 30, respectively. The first common voltage line 13 may be adjacent to the display area DA, and the second common voltage line 15 may be adjacent to the edge of the display apparatus.

The first common voltage line 13 may be configured to provide a low potential constant voltage to a light-emitting element in the display area DA. The first common voltage line 13 may extend in the Y direction mostly and wind along the shape of the island 101 and the connector 102 of the substrate 100. That is, a main portion of the first common voltage line 13 may extend in the Y direction across the plurality of islands and connectors 102. A portion of the first common voltage line 13 may branch off in the X direction and extend to the display area DA. In an embodiment, the first common voltage line 13 may be connected to the plurality of unit display parts 200.

The second common voltage line 15 may be configured to provide a low-potential constant voltage to the shield part SHP. The second common voltage line 15 may extend in the Y direction mostly and wind along the shape of the island 101 and the connector 102 of the substrate 100. That is, the main portion of the second common voltage line 15 may extend in the Y direction across the plurality of islands and connectors 102. A portion of the second common voltage line 15 may branch off in the X direction and extend to the driving circuit part 30.

The second common voltage line 15 may be provided in plurality. As an example, the second common voltage line 15 may include a (2-1)st common voltage line 151 and a (2-2)nd common voltage line 152. The (2-2)nd common voltage line 152 may be disposed between the unit driving circuit parts 30u. The (2-2)nd common voltage line 152 may wind in the Y direction and overlap the shield part SHP extending in the X direction.

In the present embodiment, because the second common voltage line 15 is configured to provide a constant voltage to the shied part SHP that overlaps the plurality of unit driving circuit parts 30u in a plan view, the unit driving circuit parts 30u may be prevented from being damaged by electrostatic discharge.

According to embodiments, the display apparatus having a transformed shape with high reliability may be implemented. However, the scope of the present disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the claims.

What is claimed is:

1. A display apparatus comprising:
a substrate including a display area and a peripheral area outside the display area, wherein the display area includes a plurality of first islands, a first connector, and a first through-portion;
a plurality of unit display parts arranged on the plurality of first islands in a one-to-one manner;
a first common voltage line and a second common voltage line arranged on one side of the peripheral area;
a driving circuit part arranged between the first common voltage line and the second common voltage line; and
a plurality of shield parts disposed on the driving circuit part and apart from each other.

2. The display apparatus of claim 1, wherein the first common voltage line is connected to the plurality of unit display parts, and
the second common voltage line is connected to the plurality of shield parts.

3. The display apparatus of claim 2, wherein the peripheral area includes a plurality of second islands, a second connector, and a second through-portion, and shapes of the plurality of second islands are the same as shapes of the plurality of first islands.

4. The display apparatus of claim 3, wherein the second common voltage line extends in one direction, and bends along shapes of the plurality of second islands and the second connector.

5. The display apparatus of claim 3, wherein the driving circuit part includes a plurality of unit driving circuit parts, and the plurality of unit driving circuit parts are arranged on the plurality of second islands, respectively.

6. The display apparatus of claim 5, wherein the plurality of shield parts overlap the plurality of unit driving circuit parts, respectively.

7. The display apparatus of claim 1, wherein a light-emitting element is arranged in each of the plurality of unit display parts,
the light-emitting element includes a pixel electrode, an emission layer, and an opposite electrode, and
the plurality of shield parts each include a same material as a material of the pixel electrode, and are provided in a same layer as a layer in which the pixel electrode is provided.

8. The display apparatus of claim 1, wherein a planarization layer is disposed between the driving circuit part and the plurality of shield parts,
the second common voltage line is disposed below the planarization layer, and
the plurality of shield parts are connected to the second common voltage line through a contact hole in the planarization layer.

9. The display apparatus of claim 8, wherein the peripheral area includes a plurality of second islands, a second connector, and a second through-portion, and
the plurality of shield parts are arranged on the plurality of second islands, respectively, and
connected to the second common voltage line through the contact hole on the plurality of second islands.

10. The display apparatus of claim 1, wherein a first planarization layer and a second planarization layer are stacked between the driving circuit part and the plurality of shield parts,
the second common voltage line is disposed between the first planarization layer and the second planarization layer, and
the plurality of shield parts are connected to the second common voltage line through a contact hole in the second planarization layer.

11. The display apparatus of claim 1, wherein the peripheral area includes a plurality of second islands, a second connector, and a second through-portion,
wherein a first planarization layer and a second planarization layer are stacked on the plurality of second islands and the second connector,
wherein the second common voltage line is disposed between the first planarization layer and the second planarization layer on the plurality of second islands, and
wherein the second common voltage line is disposed under the first planarization layer on the second connector.

12. The display apparatus of claim 1, wherein a first planarization layer and a second planarization layer are stacked between the driving circuit part and the plurality of shield parts,
wherein the second common voltage line includes a lower layer and an upper layer, the lower layer is under the first planarization layer, and the upper layer is between the first planarization layer and the second planarization layer, and
wherein the lower layer is connected to the upper layer through a contact hole.

13. The display apparatus of claim 1, wherein the driving circuit part includes a first driving circuit group and a second driving circuit group each including unit driving circuit parts,
wherein the second common voltage line includes a (2-1)st common voltage line and a (2-2)nd common voltage line, and
wherein the (2-2)nd common voltage line is arranged between the first driving circuit group and the second driving circuit group.

14. The display apparatus of claim 1, wherein the peripheral area includes a plurality of second islands, a second connector, and a second through-portion, and shapes of the plurality of second islands are different from shapes of the plurality of first islands.

15. The display apparatus of claim 14, wherein the driving circuit part includes a plurality of unit driving circuit parts, and
one of the plurality of shield parts covers an entirety of one unit driving circuit part arranged on one of the plurality of second islands.

16. A display apparatus comprising:
a substrate including a display area and a peripheral area, wherein the display area includes a plurality of first islands and a first connector, and the peripheral area including a plurality of second islands and a second connector;
a plurality of unit display parts arranged on the plurality of first islands in a one-to-one manner;
a driving circuit part in the peripheral area, configured to transfer signals to the plurality of unit display parts and including a plurality of unit driving circuit parts arranged on the plurality of second islands;
a plurality of shield parts overlapping the plurality of unit driving circuit parts, respectively;
in the peripheral area, a first common voltage line arranged between the driving circuit part and the display area; and
in the peripheral area, a second common voltage line arranged between the driving circuit part and an edge of the substrate,
wherein the plurality of shield parts are connected to the second common voltage line.

17. The display apparatus of claim 16, wherein the first common voltage line is connected to the plurality of unit display parts.

18. The display apparatus of claim 16, wherein the second common voltage line extends in one direction, and bends along shapes of the plurality of second islands and the second connector.

19. The display apparatus of claim 16, wherein a light-emitting element is arranged in each of the plurality of unit display parts,
the light-emitting element includes a pixel electrode, an emission layer, and an opposite electrode, and
the plurality of shield parts each include a same material as a material of the pixel electrode, and are provided in a same layer as a layer in which the pixel electrode is provided.

20. The display apparatus of claim 16, wherein the driving circuit part includes a first driving circuit group including first unit driving circuit parts and a second driving circuit group including second unit driving circuit parts,
wherein the second common voltage line includes a (2-1)st common voltage line and a (2-2)nd common voltage line, and
wherein the (2-2)nd common voltage line is arranged between the first driving circuit group and the second driving circuit group.
